(19) United States
(12) Patent Application Publication
(10) Pub. No.: US 2018/0122721 A1
(43) Pub. Date: May 3, 2018

(54) PLUG STRUCTURE OF A SEMICONDUCTOR CHIP AND METHOD OF MANUFACTURING THE SAME

(71) Applicant: SAMSUNG ELECTRONICS CO., LTD., SUWON-SI (KR)

(72) Inventors: SON-KWAN HWANG, Suwon-si (KR); Ho-Jin LEE, Seoul (KR); Kwang-Jin MOON, Hwaseong-si (KR); Byung-Lyul PARK, Seoul (KR); Jin-Ho AN, Seoul (KR); Nae-In LEE, Seoul (KR)

(21) Appl. No.: 15/661,135

(22) Filed: Jul. 27, 2017

(30) Foreign Application Priority Data
Nov. 1, 2016 (KR) 10-2016-0144465

(51) Int. Cl. H01L 23/48; H01L 23/485; H01L 21/768; H01L 25/065

(52) U.S. Cl. CPC H01L 23/481; H01L 23/485; H01L 2225/06513; H01L 25/0657; H01L 21/76898

(57) ABSTRACT

A plug structure of a semiconductor chip includes a substrate, an insulating interlayer disposed on the substrate, wherein the insulating interlayer includes a pad structure disposed therein, a via hole penetrating the substrate and the insulating interlayer, wherein the via hole exposes the pad structure, an insulating pattern formed on an interior surface of the via hole, wherein the insulating pattern includes a burying portion, and the burying portion fills a notch disposed in the substrate at the interior surface of the via hole, and a plug formed on the insulating pattern within the via hole, wherein the plug is electrically connected with the pad structure.

### CROSS-REFERENCE TO RELATED APPLICATION

This application claims priority under 35 U.S.C. § 119 to Korean Patent Application No. 10-2016-0144465, filed on Nov. 1, 2016, in the Korean Intellectual Property Office (KIPO), the disclosure of which is incorporated by reference herein in its entirety.

### TECHNICAL FIELD

The inventive concept relates to a semiconductor chip. More particularly, the inventive concept relates to a plug structure of a semiconductor chip and a method of manufacturing the plug structure.

### DISCUSSION OF THE RELATED ART

In a multi-chip package, stacked semiconductor chips may be electrically connected with each other by conductive connecting members. The conductive connecting members may include conductive wires, conductive bumps, etc. When the semiconductor chips are electrically connected by using the conductive bumps, a plug structure may be formed in the semiconductor chip. The plug structure may be configured to electrically connect a conductive bump with a pad of the semiconductor chip.

A via hole may be formed through a semiconductor substrate of a semiconductor chip and an insulating interlayer (e.g., an insulating layer disposed on the semiconductor substrate) to exposed the pad. During the etching process for forming the via hole, an undesirable gap may be formed at a lower end of the semiconductor substrate.

### SUMMARY

According to an exemplary embodiment of the inventive concept, a plug structure of a semiconductor chip includes a substrate, an insulating interlayer disposed on the substrate, wherein the insulating interlayer includes a pad structure disposed therein, a via hole penetrating the substrate and the insulating interlayer, wherein the via hole exposes the pad structure, an insulating pattern formed on an interior surface of the via hole, wherein the insulating pattern includes a burying portion, and the burying portion fills a notch disposed in the substrate at the interior surface of the via hole, and a plug formed on the insulating pattern within the via hole, wherein the plug is electrically connected with the pad structure.

According to an exemplary embodiment of the inventive concept, a method of manufacturing a plug structure of a semiconductor chip includes forming a via hole through a semiconductor substrate and an insulating interlayer, wherein the via hole exposes a pad structure, wherein the pad structure is disposed in the insulating interlayer, forming an insulating pattern on an inner surface of the via hole, wherein the insulating pattern includes a burying portion that fills a notch, wherein the notch is formed on the semiconductor substrate during the forming of the via hole, and forming a plug on the insulating pattern and in the via hole, wherein the plug is electrically connected with the pad structure.

According to an exemplary embodiment of the inventive concept, a multi-chip package includes a first substrate, a first semiconductor chip disposed on the first substrate, a second semiconductor chip disposed on the first semiconductor chip, wherein the first semiconductor chip is disposed between the first substrate and the second semiconductor chip, and first and second conductive bumps. The first semiconductor chip includes a second substrate having a first side and a second side opposite to the first side, wherein the first side faces the second semiconductor chip, an insulating interlayer disposed on the second side of the second substrate, a pad structure disposed in the insulating interlayer, wherein the pad structure faces the first substrate, and the pad structure is electrically connected to the first conductive bump, wherein the first conductive bump is electrically connected to the first substrate, a hole extending from the first side of the second substrate, into the second substrate and into the insulating interlayer, to the pad structure, wherein the hole exposes the pad structure, and wherein the hole includes a lateral cavity, an insulating pattern disposed in the hole, wherein the insulating pattern includes a first portion and a second portion connected to each other, wherein the first portion fills the lateral cavity, and the second portion covers an interior surface of the hole and exposes the pad structure, and a plug disposed within the hole, the plug electrically connecting the pad structure with the second conductive bump, wherein the second conductive bump is disposed on the plug and is electrically connected to the second semiconductor chip.

### BRIEF DESCRIPTION OF THE DRAWINGS

The above and other features of the inventive concept will become more apparent by describing in detail exemplary embodiments thereof in conjunction with the accompanying drawings, in which:

FIG. 1 is a cross-sectional view illustrating a plug structure of a semiconductor chip according to an exemplary embodiment of the inventive concept;

FIGS. 2 to 8 are cross-sectional views illustrating a method of manufacturing the plug structure of FIG. 1, according to an exemplary embodiment of the inventive concept; and

FIG. 9 is a cross-sectional view illustrating a multi-chip package including the plug structure of FIG. 1, according to an exemplary embodiment of the inventive concept.

### DETAILED DESCRIPTION OF THE EMBODIMENTS

Hereinafter, exemplary embodiments of the inventive concept will be explained in detail with reference to the accompanying drawings.

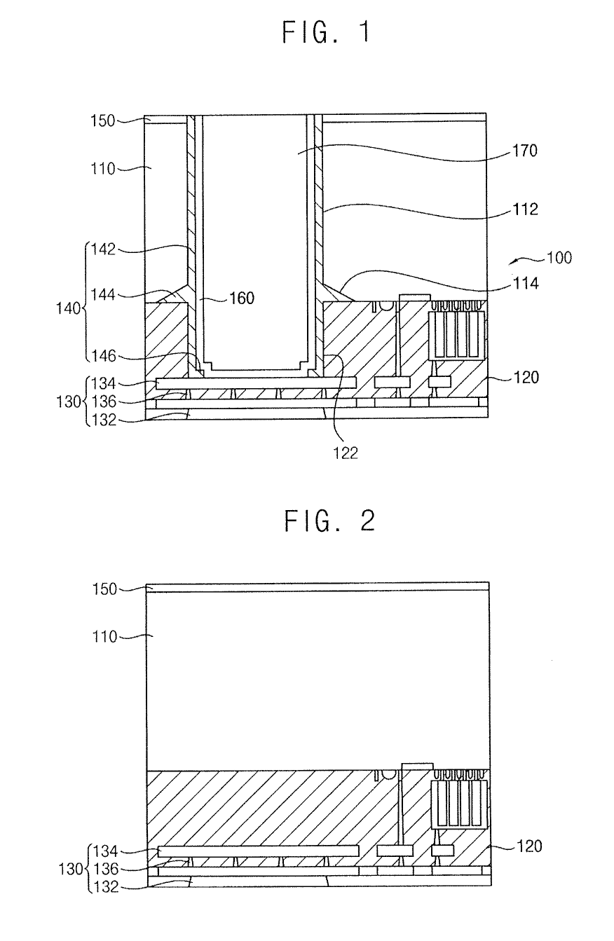

FIG. 1 is a cross-sectional view illustrating a plug structure of a semiconductor chip according to an exemplary embodiment of the inventive concept.

Referring to FIG. 1, a semiconductor chip 100 may include a semiconductor substrate 110, an insulating interlayer 120, a pad structure 130 and a plug structure.

The semiconductor substrate 110 may include silicon. The semiconductor substrate 110 may include circuitry. The circuitry may be formed, for example, in the semiconductor substrate 110.

The semiconductor substrate 110 may have a first via hole 112. The first via hole 112 may extend from an upper surface of the semiconductor substrate 110 in a downward direction. For example, the first via hole 112 may extend toward the pad structure 130. The semiconductor substrate 110 may have a notch 114 connected to the first via hole 112. The notch 114 may be formed by over-etching the semiconductor substrate 110 during a first etching process for forming the first via hole 112. The notch 114 may be formed on a lower surface of the semiconductor substrate 110. The notch 114 may contact the insulating interlayer 120. For example, the notch 114 may be formed at a lower end of an inner surface of the semiconductor substrate 110 exposed by the first via hole 112.

The insulating interlayer 120 may be formed on the lower surface of the semiconductor substrate 110. The insulating interlayer 120 may include silicon oxide. Alternatively, or additionally, the insulating interlayer 120 may include other insulating materials.

An upper surface of the insulating interlayer 120 may be exposed by the first via hole 112. In addition, the insulating interlayer 120 may have a second via hole 122. The second via hole 122 may be formed from the upper surface of the insulating interlayer 120 in the downward direction during a second etching process. Thus, the second via hole 122 may be in fluidic communication with the first via hole 112. In an exemplary embodiment of the inventive concept, the second via hole 122 is a continuation of the first via hole 112. In an exemplary embodiment of the inventive concept, the second via hole 122 is connected to the first via hole 112 and extends the first via hole 112. The pad structure 130 may be exposed by the second via hole 122. As a result, a via hole including the first via hole 112 and the second via hole 122 may be formed vertically through the semiconductor substrate 110 and the insulating interlayer 120.

The pad structure 130 may be disposed in the insulating interlayer 120. The pad structure 130 may be electrically connected with the circuit structure in the semiconductor substrate 110. The pad structure 130 may include a pad 132, metal wiring 134 (e.g., a metal wire 134) and contacts 136.

The pad 132 may be disposed on a lower surface of the insulating interlayer 120. The pad 132 may be exposed through the lower surface of the insulating interlayer 120. The pad 132 may include a metal such as, for example, aluminum.

The metal wiring 134 may be arranged horizontally in the insulating interlayer 120. The metal wiring 134 may be electrically connected with the circuitry included in the semiconductor substrate 110. The metal wiring 134 may be exposed through the second via hole 122.

The contacts 136 may be interposed between the pad 132 and the metal wiring 134 to electrically connect the pad 132 with the metal wiring 134. Thus, each of the contacts 136 may include an upper end connected to the metal wiring 134, and a lower end connected to the pad 132.

The plug structure may include an insulating pattern 140, a seed layer 160 and a plug 170.

The insulating pattern 140 may be formed on the inner surface of the via hole that includes the first via hole 112 and the second via hole 122. The insulating pattern 140 may include a vertical portion 142, a burying portion 144 and a horizontal portion 146. The insulating pattern 140 may include an insulating material. For example, the insulating pattern 140 may include a polymer. For example, the insulating pattern 140 may include a polymer having a low viscosity. Alternatively, the insulating pattern 140 may include other insulating materials.

The vertical portion 142 may be formed on the inner surface of the via hole. For example, the vertical portion 142 may be formed on the inner surface of the first via hole 112 and the inner surface of the second via hole 122. The horizontal portion 146 may be horizontally extended from an inner lower end of the vertical portion 142. The horizontal portion 146 may be disposed on an upper surface of the metal wiring 134. For example, the horizontal portion 146 may be disposed on an edge portion of the upper surface of the metal wiring 134 to expose a central portion of the metal wiring 134. The horizontal portion 146 may be integrally formed with the vertical portion 142. The vertical portion 142 and the horizontal portion 146 may be simultaneously formed by a process of forming the insulating pattern 140.

The burying portion 144 may be horizontally formed on an outer surface of the vertical portion 142. The burying portion 144 may fill an inner space of the notch 114. Therefore, the burying portion 144 may have a shape substantially the same as the shape of the notch 114. The burying portion 144 may be integrally formed with the vertical portion 142. For example, the burying portion 144 and the vertical portion 142 may be simultaneously formed by the same process used to form the insulating pattern 140.

Because the notch 144 may be fully filled by the burying portion 144, the seed layer 160 and the plug 170 may be formed in the via hole. In an exemplary embodiment of the inventive concept, the seed layer 160 and the plug 170 do not protrude into the notch 114 since the notch 114 is filled by the burying portion 144. Thus, the seed layer 160 and the plug 170 may have an increased step coverage. For example, the notch 114 may be an undesirable gap, and the undesirable gap may be fully filled by the burying portion 144. Thus, since the undesirable gap is covered by the burying portion 144, the seed layer 160 and the plug 170 may have an increased gap coverage. Accordingly, the seed layer 160 and the plug 170 may have a uniform thickness by not protruding into the notch 114. In addition, a surface of the vertical portion 142, which faces the plug 170, may be sufficiently even and might not have gaps, steps or cavities. In this case, sufficiently even may refer to a surface which has no gaps, steps or cavities, or to a surface that includes gaps, steps or cavities that are small enough to not affect the structural strength, resistance and integrity of the seed layer 160 and plug 170.

The seed layer 160 may be formed on the insulating pattern 140 and the pad structure 130. For example, the seed layer 160 may be formed on the vertical portion 142 and the horizontal portion 146 of the insulating pattern 140, and on the metal wiring 134 of the pad structure 130.

The plug 170 may be formed on the seed layer 160 to fill up the via hole. The plug 170 may be formed by a physical vapor deposition (PVD) process performed on the seed layer 160.

Additionally, the plug structure may further include a polishing stop layer 150. The polishing stop layer 150 may be formed on the upper surface of the semiconductor substrate 110. The polishing stop layer 150 may be formed on the upper surface of the semiconductor substrate 110 before the first etching process is performed to form the first via hole 112. Thus, the polishing stop layer 150 may be arranged between a portion of the insulating pattern on the semiconductor substrate 110 and the upper surface of the semiconductor substrate 110. A chemical mechanical polishing (CMP) process may be performed until the polishing stop layer 150 is exposed to remove portions of the insulating pattern 140, the seed layer 160 and the plug 170 on the semiconductor substrate 110. The polishing stop layer 150 may include oxide.

FIGS. 2 to 8 are cross-sectional views illustrating a method of manufacturing the plug structure in FIG. 1, according to an exemplary embodiment of the inventive concept.

Referring to FIG. 2, the insulating interlayer 120 may be formed on the lower surface of the semiconductor substrate 110. The pad structure 130 may be formed in the insulating interlayer 120. The polishing stop layer 150 may be formed on the upper surface of the semiconductor substrate 110.

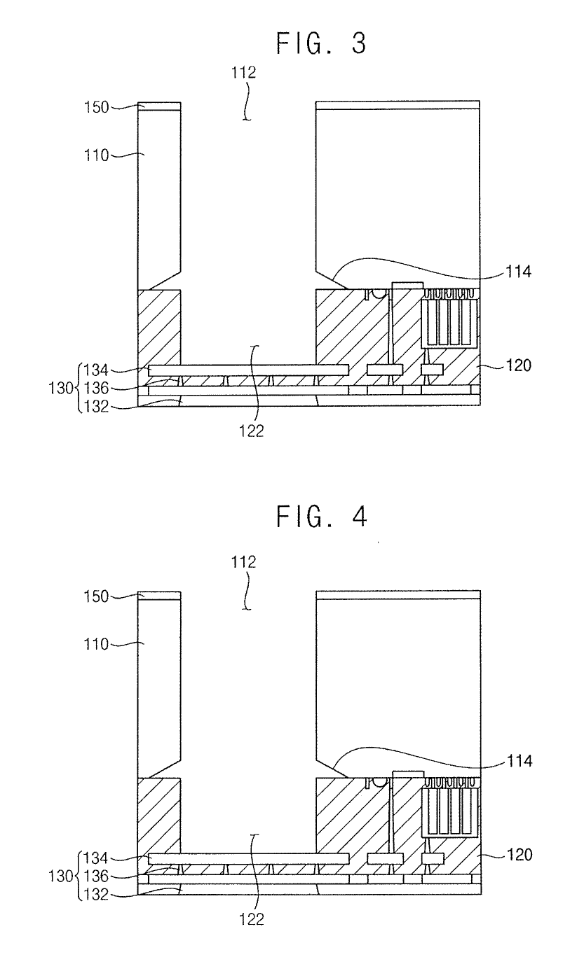

Referring to FIG. 3, the first etching process may be performed on the semiconductor substrate 110 to form the first via hole 112. The first via hole 112 may be vertically formed through the polishing stop layer 150 and the semiconductor substrate 110 to expose the insulating interlayer 120. For example, the first etching process may be performed until the insulating interlayer 120 is exposed.

When the insulating interlayer 120 is exposed, the first etching process may be continued to be performed on the semiconductor substrate 110. In this case, the lower surface of the semiconductor substrate 110, making contact with the insulating interlayer 120, may be over-etched to form the notch 114 at the lower surface of the semiconductor substrate 110.

Referring to FIG. 4, the second etching process may be performed on the insulating interlayer 120 to form the second via hole 122. The second via hole 122 may be vertically formed through the insulating interlayer 120 to expose the metal wiring 134 of the plug structure 130. For example, the second etching process may be performed until the metal wiring 134 is exposed. After performing the second etching process, the via hole, which includes the first and second via holes 112 and 122, may be formed. The via hole may be configured to exposed the plug structure 130.

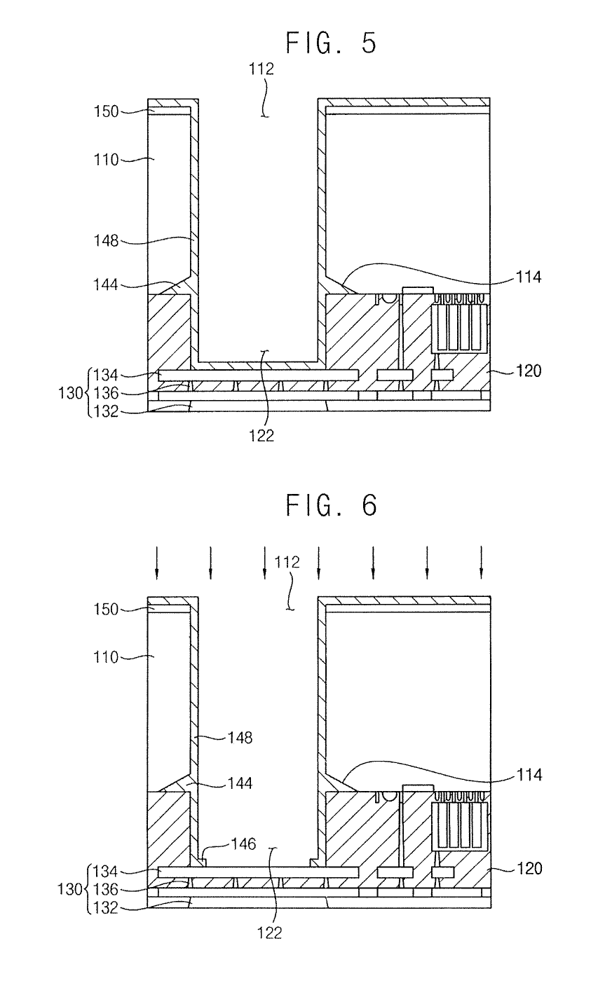

Referring to FIG. 5, an insulating layer 148 may be formed on the upper surface of the semiconductor substrate 110, the inner surface of the via hole and the upper surface of the metal wiring 134. The insulating layer 148 may be configured to cover the upper surface of the metal wiring 134. The insulating layer 148 may be formed by coating a polymer having a low viscosity on the upper surface of the semiconductor substrate 110, the inner surface of the via hole and the upper surface of the metal wiring 134. Alternatively, the insulating layer 148 may be formed by a chemical vapor deposition (CVD) process.

The insulating layer 148 may have the burying portion 144, which is configured to bury the notch 114. The polymer may be coated on the upper surface of the semiconductor substrate 110, the inner surface of the via hole and the upper surface of the metal wiring 134 to form the insulating layer 148. The insulating layer 148 includes the burying portion 144. Thus, the polymer fills the notch 114 with the burying portion 144. The insulating layer 148 may have the vertical portion 142 on the inner surface of the via hole.

Referring to FIG. 6, the portion of the insulating layer 148 on the metal wiring 134 may be removed to form the horizontal portion 146 of the insulating pattern 140. This may expose the central portion of the metal wiring 134. The portion of the insulating layer 148 on the metal wiring 134 may be removed by a lithography process.

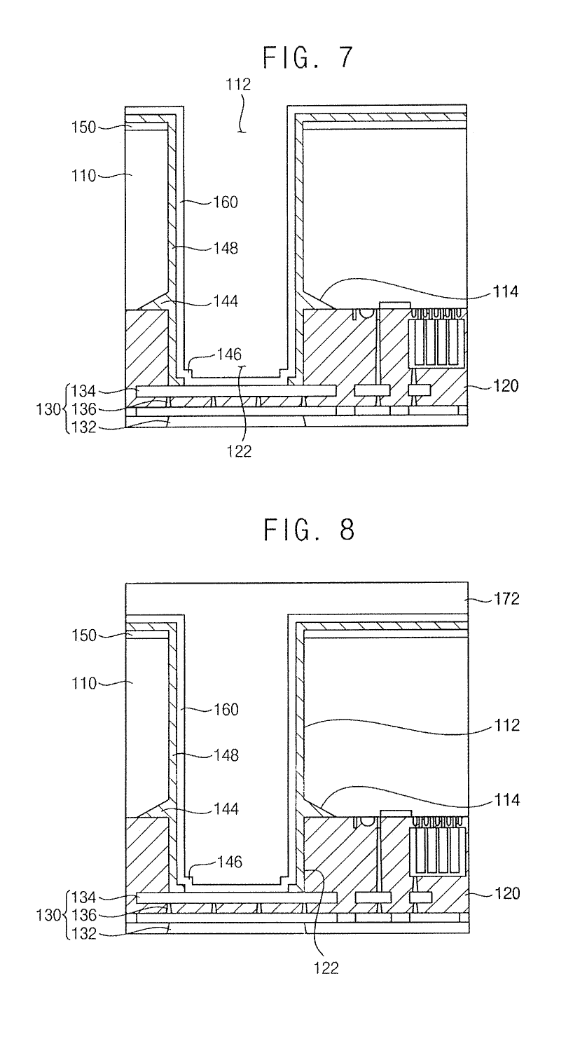

Referring to FIG. 7, the seed layer 160 may be formed on the insulating layer 148 and the metal wiring 134. The seed layer 160 may include a metal. Because the notch 114 is filled with the burying portion 144, the seed layer 160 may have a uniform thickness.

Referring to FIG. 8, a PVD process may be performed on the seed layer 160 to form a preliminary plug 172 on the seed layer 160. The preliminary plug 172 may fill the via hole and the preliminary plug 172 may be positioned on the semiconductor substrate 110.

The CMP process may be performed until the polishing stop layer 150 is exposed to remove the portions of the preliminary plug 172, the seed layer 160 and the insulating layer 148 on the semiconductor substrate 110. Accordingly, the plug structure of FIG. 1 may be completed. Thus, the insulating pattern 140 including the vertical portion 142, the burying portion 144 and the horizontal portion 146 may be formed. Further, the plug 170 may be configured to fill the via hole.

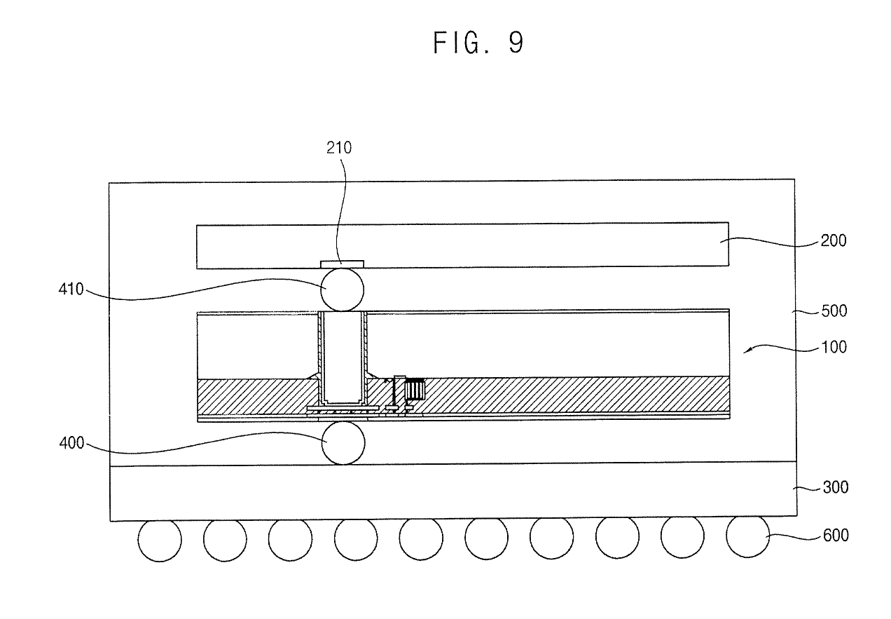

FIG. 9 is a cross-sectional view illustrating a multi-chip package including the plug structure of FIG. 1, according to an exemplary embodiment of the inventive concept.

Referring to FIG. 9, a multi-chip package, according to an exemplary embodiment of the inventive concept, may include a package substrate 300, a first semiconductor chip 100, a second semiconductor chip 200, first and second conductive bumps 400 and 410, a molding member 500 and external terminals 600.

The package substrate 300 may include an insulating substrate and conductive patterns. The conductive patterns may be formed in the insulating substrate. Each of the conductive patterns may include an upper end exposed through an upper surface of the insulating substrate, and a lower end exposed through a lower surface of the insulating substrate.

The first semiconductor chip 100 may be arranged on the package substrate 300. In an exemplary embodiment of the inventive concept, the first semiconductor chip 100 may have a structure substantially the same as that of the semiconductor chip 100 of FIG. 1. Thus, the same reference numerals may refer to the same elements and any omitted description may be assumed to be similar to that of corresponding elements.

The first conductive bump 400 may be interposed between the package substrate 300 and the first semiconductor chip 100. The first conductive bump 400 may be electrically connected between the upper end of the conductive pattern in the package substrate 300 and the pad 132 of the first semiconductor chip 100.

The second semiconductor chip 200 may be stacked on the first semiconductor chip 100. The second semiconductor chip 200 may include a pad 210. The pad 210 may be disposed on a lower surface of the second semiconductor chip 200.

The second conductive bump 410 may be interposed between the first semiconductor chip 100 and the second semiconductor chip 200. The second conductive bump 410 may be electrically connected between the plug 170 of the first semiconductor chip 100 and the pad 210 of the second semiconductor chip 200.

The molding member 500 may be formed on the package substrate 300 to cover the first semiconductor chip 100 and the second semiconductor chip 200. The molding member 500 may include an epoxy molding compound (EMC).

The external terminals 600 may be mounted on the lower surface of the package substrate 300. The external terminals 600 may be electrically connected to the lower ends of the conductive patterns in the package substrate 300. The external terminals may include solder balls.

In an exemplary embodiment of the inventive concept, the multi-chip package may include the two semiconductor chips 100 and 200. Alternatively, the multi-chip package may include at least three semiconductor chips. In this case, the semiconductor chips, except for an upper most semiconductor chip, may include the plug structure of the semiconductor chip 100 of FIG. 1.

According to an exemplary embodiment of the inventive concept, the burying portion that is configured to bury the notch may be integrally formed with the insulating pattern on the inner surface of the via hole. Thus, coverage of an undesirable step caused by the notch may be prevented.

While the inventive concept has been particularly shown and described with reference to exemplary embodiments thereof, it will be apparent to those of ordinary skill in the art that various changes in form and detail may be made therein without departing from the spirit and scope of the inventive concept.

What is claimed is:

1. A plug structure of a semiconductor chip, comprising:
a substrate;
an insulating interlayer disposed on the substrate, wherein the insulating interlayer includes a pad structure disposed therein;
a via hole penetrating the substrate and the insulating interlayer, wherein the via hole exposes the pad structure;
an insulating pattern formed on an interior surface of the via hole, wherein the insulating pattern includes a burying portion, and the burying portion fills a notch disposed in the substrate at the interior surface of the via hole; and
a plug formed on the insulating pattern within the via hole, wherein the plug is electrically connected with the pad structure.

2. The plug structure of the semiconductor chip of claim 1, wherein the insulating pattern comprises:
a vertical portion disposed on the interior surface of the via hole, the vertical portion including the burying portion; and
a horizontal portion extending from an end of the vertical portion, wherein the horizontal portion is disposed on the pad structure.

3. The plug structure of the semiconductor chip of claim 1, wherein the insulating pattern comprises a polymer.

4. The plug structure of the semiconductor chip of claim 1, further comprising a seed layer interposed between the insulating pattern and the plug.

5. The plug structure of the semiconductor chip of claim 1, wherein the pad structure comprises:
a pad exposed through a lower surface of the insulating interlayer; and
a metal wire disposed in the insulating interlayer and exposed through the via hole, wherein the metal wire is electrically connected with the pad.

6. The plug structure of the semiconductor chip of claim 1, wherein the notch is formed at a location where the substrate contacts the insulating interlayer.

7. The plug structure of the semiconductor chip of claim 1, further comprising a polishing stop layer disposed on the substrate.

8. A method of manufacturing a plug structure of a semiconductor chip, comprising:
forming a via hole through a semiconductor substrate and an insulating interlayer, wherein the via hole exposes a pad structure, wherein the pad structure is disposed in the insulating interlayer;
forming an insulating pattern on an inner surface of the via hole, wherein the insulating pattern includes a burying portion that fills a notch, wherein the notch is formed on the semiconductor substrate during the forming of the via hole; and
forming a plug on the insulating pattern and in the via hole, wherein the plug is electrically connected with the pad structure.

9. The method of claim 8, wherein forming the via hole comprises:
etching the semiconductor substrate to form a first via hole and the notch, wherein the first via hole exposes the insulating interlayer; and
etching the insulating interlayer to form a second via hole, wherein the second via hole exposes the pad structure.

10. The method of claim 8, wherein forming of the insulating pattern comprises:
forming an insulating layer on an upper surface of the semiconductor substrate, the inner surface of the via hole, in the notch and on an upper surface of the pad structure; and
partially removing the insulating layer on the pad structure to expose the pad structure.

11. The method of claim 10, wherein the forming of the insulating layer comprises coating a polymer on the upper surface of the semiconductor substrate, the inner surface of the via hole, in the notch and on the upper surface of the pad structure.

12. The method of claim 8, wherein the forming of the plug comprises:
forming a seed layer on the insulating pattern; and
forming the plug on the seed layer.

13. The method of claim 12, wherein the forming of the plug on the seed layer comprises:
forming a preliminary plug by performing a physical vapor deposition (PVD) process on the seed layer; and
removing portions of the preliminary plug, the seed layer and the insulating pattern.

14. The method of claim 13, wherein the portions of the preliminary plug, the seed layer and the insulating pattern are removed by a chemical mechanical polishing (CMP) process.

15. The method of claim 14, further comprising forming a polishing stop layer between the semiconductor substrate and the insulating pattern,
wherein the CMP process is performed until the polishing stop layer is exposed.

16. A multi-chip package, comprising:
a first substrate;
a first semiconductor chip disposed on the first substrate;
a second semiconductor chip disposed on the first semiconductor chip, wherein the first semiconductor chip is disposed between the first substrate and the second semiconductor chip; and
first and second conductive bumps,
wherein the first semiconductor chip includes:
a second substrate having a first side and a second side opposite to the first side, wherein the first side faces the second semiconductor chip;
an insulating interlayer disposed on the second side of the second substrate;
a pad structure disposed in the insulating interlayer, wherein the pad structure faces the first substrate, and the pad structure is electrically connected to the first conductive bump, wherein the first conductive bump is electrically connected to the first substrate;
a hole extending from the first side of the second substrate, into the second substrate and into the insulating interlayer, to the pad structure, wherein the hole exposes the pad structure, and wherein the hole includes a lateral cavity;
an insulating pattern disposed in the hole, wherein the insulating pattern includes a first portion and a second portion connected to each other, wherein the first portion fills the lateral cavity, and the second portion covers an interior surface of the hole and exposes the pad structure; and
a plug disposed within the hole, the plug electrically connecting the pad structure with the second conductive bump, wherein the second conductive bump is disposed on the plug and is electrically connected to the second semiconductor chip.

17. The multi-chip package of claim 16, wherein the lateral cavity is disposed between the insulating interlayer and the second substrate.

18. The multi-chip package of claim 17, wherein the first portion of the insulating pattern fills the lateral cavity such that a surface of the second portion of the insulating pattern, which faces the plug, is even.

19. The multi-chip package of claim 16, wherein the pad structure includes a metal wire electrically connected to the plug and to an electrical circuit disposed in the first semiconductor chip, a pad electrically connected to the first conductive bump, and at least one contact disposed between the metal wire and the pad to electrically connect the metal wire with the pad.
